(19) United States
(12) Patent Application Publication
(10) Pub. No.: US 2008/0259417 A1
(43) Pub. Date: Oct. 23, 2008

(54) Holographic Recording Media

(76) Inventor: John David Wiltshire, Cambridgeshire (GB)

Correspondence Address: TAROLLI, SUNDHEIM, COVELL & TUMMINO L.L.P., 1300 EAST NINTH STREET, SUITE 1700, CLEVEVLAND, OH, 44114, US

(21) Appl. No.: 11/814,468

(22) PCT Filed: Jan. 23, 2006
(86) PCT No.: PCT/GB2006/050019

§ 371 Date: Mar. 11, 2008

Related U.S. Application Data
(60) Provisional application No. 60/651,612, filed on Feb. 11, 2005.

(30) Foreign Application Priority Data
Jan. 21, 2005 (GB) 0501214.1

(51) Int. Cl. G03H 1/02; G02B 5/32; G03F 7/004

(52) U.S. Cl. 359/3; 359/15; 430/2

(57) ABSTRACT

This invention relates to improved holographic recording media and to related methods and apparatus for fabricating and reading holograms.

A holographic recording medium comprising: a carrier; and a photosensitive recording layer carried by said carrier, and wherein said recording medium further comprises: an optical filter, said filter comprising a bandpass filter defining at least one optical transmission window for recording a hologram in said photosensitive recording layer.

This invention relates to improved holographic recording media and to related methods and apparatus for fabricating and reading holograms.

Holograms have many uses but one increasingly important application is that of security, where a hologram may be used as an anti-counterfeiting device on security documents such as passports, visas, identity cards, driver licences, government bonds, Bills of Exchange, banknotes and the like, as well as on packaging and labelling. To improve security special visual effects may sometimes be employed such as kinetic effects, for example the appearance/disappearance of graphic elements (sometimes termed Kinegram™), or contrast/brightness variation effects, for example a graphic converting from a positive to a negative image (a Pixelgram™). It will be appreciated, however, that there is scope for improved holographic techniques which contribute to increased security or which exhibit other desirable traits such as increased brightness and/or an improved visually aesthetic appearance.

In this specification we are particularly (but not exclusively) concerned with volume reflection holography. Broadly speaking a reflection hologram is a hologram which is constructed by interfering object and reference beams which are directed onto a recording medium from opposite sides of the medium. Embodiments of the techniques described herein exploit this (as described in more detail later) since because the object and reference beams must have the same wavelength, by restricting the range of wavelengths impinging on one side of the hologram the range of wavelengths usable to fabricate the hologram is effectively limited.

A volume hologram is, here, a hologram in which the angle difference between the object and reference beams is equal to or greater than 90 degrees. Volume holograms are sometimes referred to as “thick” holograms since, roughly speaking, the fringes are in planes approximately parallel to the surface of the hologram, although in practice the thickness of the recording medium can vary significantly, say between 1 μm and 100 μm, and is typically around 7 μm.

Volume holograms, and in particular volume reflection holograms, have special security advantages because they are particularly difficult to copy although they are not well suited to mass production. One property of volume holograms which is employed in the embodiments of the techniques described herein, is that an image replayed by a volume hologram has a well-defined colour—that is when illuminated from a broadband source (or at the correct wavelength) it will reflect over only a narrow wavelength band the fill width at half maximum of the peak depends upon the thickness of the recording medium, a thicker medium resulting in a narrower peak. Thus an image replayed by a volume hologram has a specific spectral colour; however more than one image may be stored and replayed and these different images may have different colours. To replay a stored image the angle of incident illumination must be approximately correct; if the hologram is tilted away from this correct angle the diffraction efficiency falls off rapidly (although the colour of the replayed image generally remains substantially the same).

Typical hologram recording materials include (but are not limited to) dichromated gelatine (DCG), silver halide, and photopolymer based materials. This material is generally mounted on a carrier, typically polyester, although other carriers such as triacetate or cellulose nitrate may be used. The carrier is typically of the order of ten times the thickness of the gelatin emulsion, for example ˜75 μm thick, although carrier thickness can potentially range between ˜5 μm and ˜500 μm.

The step of recording the hologram generally involves exposing the hologram to interfering light beams followed by subsequent processing to “fix” the hologram. The particular processing steps after exposure it will be appreciated depend upon the recording layer and may comprise, for example, developing techniques similar to those used for conventional photographic film, or other techniques such as (cross) polymerisation and/or baking.

The techniques we describe herein are suitable for use with any conventional holographic recording material and carrier, including but not limited to those described above.

According to a first aspect of the present invention there is provided a holographic recording medium comprising: a carrier; and a photosensitive recording layer carried by said carrier; and wherein said recording medium further comprises: an optical filter, said filter comprising a bandpass filter defining at least one optical transmission window for recording a hologram in said photosensitive recording layer.

Defining an optical transmission window makes counterfeiting of a recorded hologram more difficult. Preferably the transmission window is narrow, for example having a full width and half maximum (FWHM) of less than 100 nm, less than 50 nm, or more preferably less than 20 nm, 10 nm, 5 nm, or even 1 mm. In this way the transmission wavelengths can be centred precisely on a laser wavelength, preferably a relatively unusual laser wavelength, for example the 594 nm yellow helium neon laser wavelength. Using a single optical transmission window with, say, a volume reflection hologram provides a system in which the background, for example a substrate viewed through the hologram, and the hologram itself are substantially the same colour, which can make the hologram difficult to see. In some situations this may be an advantage since, generally, the hologram will be machine-readable. To facilitate this a plane of an image replayed by the hologram may be shifted away from (in front or behind of) a physical plane of the hologram so that, for example, an image capture apparatus with a limited depth of field may be employed to separate the replayed image from the background.

In preferred embodiments, however, the optical filter defines two optical transmission windows at different wavelengths, one for recording the hologram, the other for replay of a stored holographic image. Preferably one or both transmission windows are relatively narrow, as previously defined, and preferably (but not essentially) they are substantially non-overlapping. Conveniently this may be achieved using a film base which filters the light into two colour windows to allow exposure at one wavelength and then viewing at another by, for example, modifying the hologram after exposure. Preferably the viewing wavelength is incompatible with standard laser wavelengths, for example one or more laser wavelengths selected from the list 647 nm (Kr), 633 nm (HeNe), 550 nm, 532 nm (YAG), 525 nm, 514 nm (Al), 488 nm (Ar), 458 nm (Ar and DPSS), 413 nm (Kr), or preferably all of these. In this context “incompatible” can be taken to mean a transmission of less than 50 percent, 25 percent, 10 percent, 5 percent or 1 percent at the relevant wavelength or wavelengths.

It is here noted that the recording and/or replay wavelengths need not be visible wavelengths—for example an image could be recorded in, say, the red, green or blue and then shifted by, say, chemical processing to replay in the infrared or ultraviolet. In this specification generally references to light and optics are not limited to visible light and optics therefore.

In embodiments the photosensitive recording layer comprises a material which is physically or chemically processable to shift a replay wavelength of a holographic image away from a recording wavelength of the image. This is why a filter defining two (or more) transmission windows is desirable. However in other embodiments a single transmission window may be employed.

One example of a physical technique for shifting a recording or replay image uses a humidity sensitive recording material such as a gel-based recording material. This may be pre-swollen in a humidity cabinet (preferably using steam for speed), exposed, and then dried to shrink the hologram. In this way, for example, an image recorded in the red can replay in the blue, A similar procedure may be used in reverse to shift a replay wavelength towards the red. Additionally or alternatively a material such as a water soluble polymer may be incorporated into one or both of the carrier and the photosensitive recording layer, either at manufacture (then being removed by later processing) or following exposure to record a hologram, depending upon whether a shift towards the blue or red is desired. Other techniques involve chemical processing, for example increasing the volume of a gelatin recording layer with a swelling agent. The inclusion of a salt such as chrome alum which causes cross-linking in the gelatin retains some of the salt within the layer after subsequent drying thus increasing the thickness of the layer, and hence fringe spacing, shifting the replayed image towards the red. In a still further example developing a silver halide film with, for example, dichromate results in silver sulphate leaving the film which thus contracts, shifting the fringe spacing towards the blue; a similar shift can be obtained using so-called Van renesse bleach on a silver halide emulsion (“Efficiency of Bleaching Agents for Holography”, R L Van Renesse and R A J Bouts, Optik, 1973.) The optical filter may be implemented by impregnating the carrier with a dye or a combination of dyes to define the one or more transmission windows. Such procedures are well known to those skilled in the art and are often used, for example, for the fabrication of polyester solar control films (for an example see EP 0 587 282, Courtaulds plc). Additionally or alternatively an optical filter layer may be provided, for example between the carrier and the photosensitive layer (although for a holographic recording medium for volume reflection holography (interfering beams from opposite faces of the recording medium) in principle such a filter layer could be placed at any position within the structure. Such a filter layer may, for example, be vacuum coated onto the carrier, either firmly or be sputtering, or transfer coated onto the carrier. The filter layer may comprise one or more of a metallisation layer, a multilayer coating, for example to provide an interference filter, or a dichroic coating (which is less sensitive to illumination angle than an interference filter). Suitable materials may be obtained from Courtaulds plc., in the UK; there are many companies which are able to provide coated polyester and other polymer films, for example CP Films, hic., of Martinsville, Va. USA. Preferably the filter material is chosen such that a transmission window has a peak transmission of greater than 50 percent, preferably greater than 75 percent, 80 percent or 85 percent.

As previously mentioned, preferably the holographic recording medium is suitable for recording a volume reflection hologram, in particular for security purposes.

The invention also provides a holographic recording medium as described above in which a hologram, in particular a volume reflection hologram, has been recorded. Preferably the hologram is of a biometric image such as a fingerprint, face or iris.

Thus in a further aspect the invention provides a recorded hologram incorporating an optical filter, said filter having less than 50 percent transmission at a plurality, preferably all of laser wavelengths 647 nm, 633 nm, 532 μm, 514 nm, 488 nm, 458 nm, 413 nm, whereby said filter is configured to inhibit replay of a hologram using any of said laser wavelengths.

According to another aspect of the invention there is therefore provided a volume reflection hologram incorporating an optical filter, said filter having two different transmission windows, one overlapping a replay wavelength of said hologram.

In an embodiment one of the transmission windows provides a transmission at the replay wavelength of the hologram of greater than 50 percent whilst the other window provides a transmission of less than 50 percent at this replay wavelength. Preferably the transmission window overlapping the replay wavelength provides a transmission of, 60 percent, 75 percent or more at the replay wavelength.

A hologram as described above can be mounted on a substrate which may comprise any convenient material including, but not limited to, paper, plastic, glass, metal and the like; some particularly preferred methods for this are described in tie applicant's co-pending UK Patent Application No 0426571.6 entitled “Hologram Fabrication Methods” filed on 3 Dec. 2004. When mounted on a carrier the photosensitive recording layer is preferably disposed between the substrate and the optical filter, and in this case will generally therefore be disposed between the substrate and tile carrier. In this way the hologram is in effect mounted “upside down” on the substrate; it may be attached by any convenient adhesive, for example a transfer adhesive.

For security applications the substrate may comprise a security document or banknote; preferably this is printed and the hologram at least partially overlays the printing so that the printing is visible through the hologram by means of its transmission window or windows. For example where two transmission windows are provided at a recording wavelength and a replay wavelength of the hologram the print under the hologram will appear in a combination of the two wavelengths (assuming broadband illumination) whereas the hologram will appear at its replay wavelength. Alternatively when illuminated at the replay wavelength both the hologram and print will be seen whereas when illuminated at the recording wavelength just the print will be seen (facilitating separation of the two); when illuminated at a wavelength different to both the recording wavelength and the replay wavelength (or at least different to transmission windows defined by these wavelengths) neither the hologram nor the print will be seen and generally the hologram/substrate combination will appear black. Some particular advantageous techniques for reading holograms are described in the applicant's co-pending UK Patent Application No 0501215.8 entitled “Hologram Imaging Techniques and Holograms” filed on 21 Jan. 2005, and in the corresponding PCT application.

In another aspect the invention provides a method of fabricating a hologram using a recording medium having two transmission windows, the method comprising: recording said hologram using a first of said windows; the method further comprising: processing said recording medium such that said recorded hologram replays within a second of said windows.

In embodiments the boundaries of the transmission windows may be taken as the level at which transmission falls to 50 percent or as defined by the half maximum of the transmission peak. It will be appreciated that the replay wavelength of the recorded hologram need not necessarily be centred upon the second window; preferably, however, the first window has a transmission of less than 50 percent, 30 percent, 20 percent or 10 percent at the replay wavelength of the recorded hologram. It will be appreciated that, as described above, the recording medium may be processed either before or after recording a hologram to shift the replay wavelength with respect to a wavelength used for recording the hologram. Again, as previously described, physical and/or chemical processing may be employed.

In another aspect the invention provides apparatus for reading a hologram incorporating an optical filter with at least one transmission window, the apparatus comprising: at least one light source to illuminate said hologram at a plurality of wavelengths; and means to determine a response of said hologram at said plurality of wavelengths.

In a preferred embodiment the apparatus also includes means to verify the hologram by verifying the response of the hologram at the plurality of wavelengths. Preferably the plurality of wavelengths comprises a plurality of discrete wavelengths, for example the apparatus using a set of LED's (or other sources) with at least one emitting at a wavelength in each transmission window and at least one having a wavelength substantially outside the transmission windows. In this way “a fingerprint” of the optical filter may be obtained and used to verify the hologram in a straight forward manner, in a simple system without the need to verify the stored image.

These and other aspects of the invention will now be further described by way of example only, with reference to the accompanying figures in which:

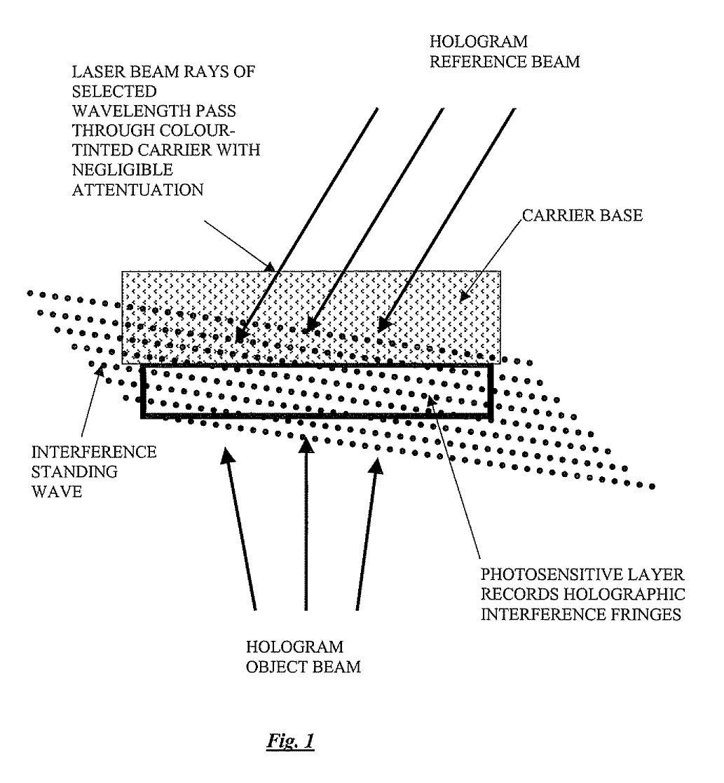

FIG. 1 shows a cross-section through a holographic recording medium incorporating an optical filter according to an embodiment of the present invention;

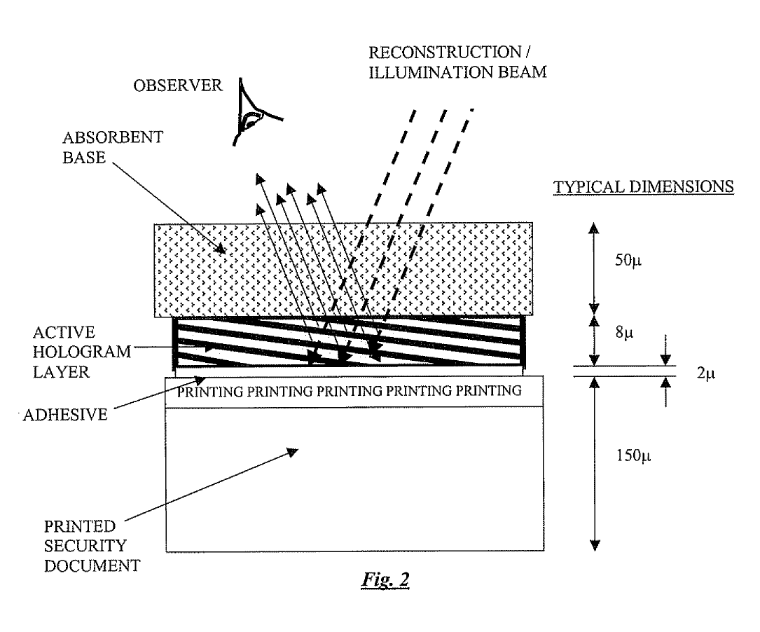

FIG. 2 shows illumination of a security document bearing the hologram of FIG. 1;

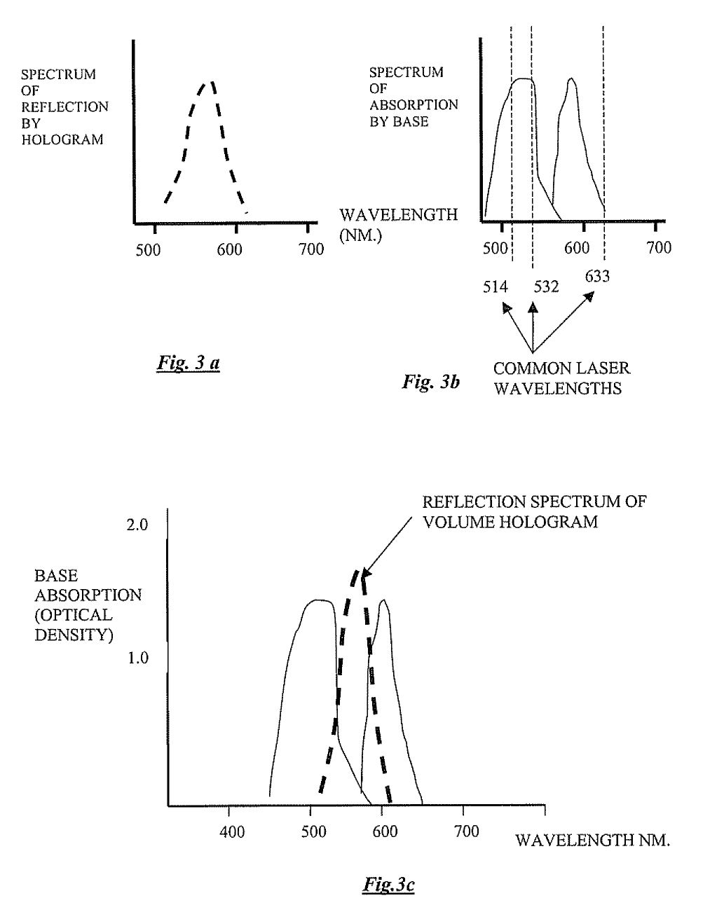

FIGS. 3a to 3c show a spectra associated with the recording medium of FIG. 1; and

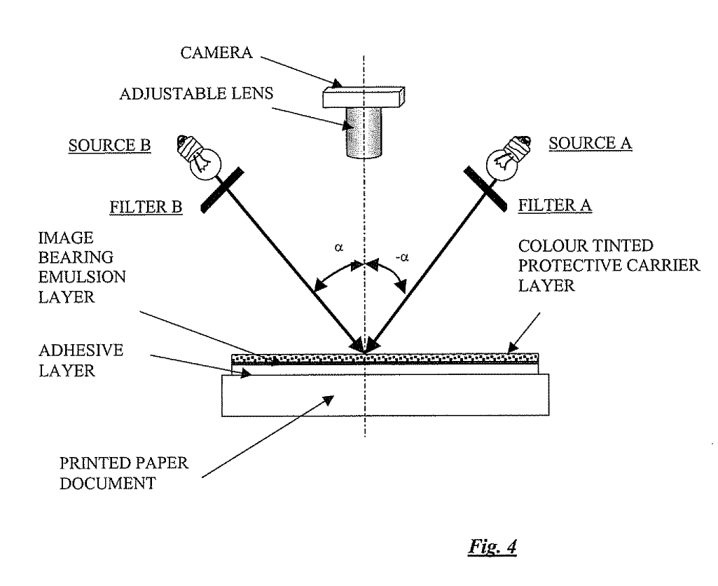

FIG. 4 shows an example of apparatus for reading the hologram of FIG. 1.

It is usual in the manufacture of silver halide and certain other photographic recording materials that coloured carrier or base materials and underlayers to the recording emulsion are incorporated into a coating routine. Since photographic material is predominantly used to record amplitude images focussed onto the surface of the film by a lens system, light arrives at the recording medium from only the front surface. Functional dyes and pigments may be incorporated in the layer in such a way as to absorb unwanted transmission or internal reflection or scatter within the layer to improve the sharpness and clarity of the recorded image.

Holographic recording materials created by manufacturers such as Agfa Gevaert, since the simultaneous invention of modern holography accredited to Leith and Upatnieks in the USA and Denisyuk in the Soviet Union in the 1960's, until the withdrawal of Agfa from supply of holographic materials in 1998 have been coated with an anti-halation layer where their use is designated as transmission holography. In the case of transmission hologram recording, laser beams designated object and reference beams, arrive from the same side of the recording material and the standing wave of interference between them is thus recorded in the photosensitive layer. In order to enable accessibility to this entire fringe structure to the light later used to reconstruct the holographic image, holographers invented the concept of bleaching the developed silver metal in silver halide holograms such that the black metal is removed or converted to material which does not absorb significant amounts of light.

Advantageously, this technique may create components within the layer, which have a significantly higher or lower index of refraction than the components adjacent to them. This index variation within the medium is able to introduce phase change rather than attenuation to rays of light travelling through the layer as a conjugate of the original laser reference beam, and result in reconstruction of the original object wavefront in a particularly efficient way, which yields a bright holographic image reconstruction.

In other materials, such as dichromated gelatin and photopolymers, which may capable of sustaining a fringe structure suitable for a volume reflection hologram, the refractive index modulation within the layer is achieve by agglomeration or polymerisation of molecules of the original layer in order to create similar zones of high or low index relative to adjacent zones.

Both thin and thick holograms of this type have been made in a multitude of application areas. Manufacturers of embossed hologram surface relief masters frequently use coatings of photoresist material produced by the Shipley company in Germany and coated by companies such as Towne Inc., USA.

Towne Inc. typically use Chromium or Ferric Oxide underlayers in order to provide anti-halation properties by absorbing spurious reflections and scatter within the layer and thus enhance the quality of the recorded diffraction grating.

For volume reflection holography, however there is a fundamental requirement for the recording layer to intersect the direction of the object and reference beams in such a way that the standing wave of interference is recorded within the depth of the layer, with its predominantly planar fringes approximately parallel in a least one plane to the recording layer. This requirement inevitably means that the carrier and the photosensitive layer itself must be predominantly transparent towards light of the wavelength dictated by the laser source selected for the imaging process required to create the holographic fringe structure.

Traditionally, the carrier film layer has been used a protective layer after completion of the hologram so that the carrier, which may be a relatively durable. Thus the emulsion side of the assembly is generally coated with adhesive and attached to a paper document so that the emulsion, which may be sensitive to pressure, abrasion, creasing, moisture or even humidity, is protected from these influences by the durable base layer.

The system we describe allows for special base materials with specific colour properties to be used in such a way as to add enhanced security to the finished product in a number of ways. We can consider the properties of the base in relation to the lasers to be used and in relation to the hologram resulting from the completion of the chemical processing or physical processing of the layer. But the fringe frequency after this processing may differ from the frequency of the actual standing wave which gave rise to the hologram, because the contraction or expansion of the layer may extend or contract the breadth of the fringes and the spacing between them, as a function tie angle they subtend with the plane of the layer.

Thus, we are able to record a holographic image with a laser at a chosen wavelength and select a chemistry process which results in an image that replays at a different point in the visible spectrum or indeed at the infra red or ultra violet ends of the range of wavelengths visible to the human eye.

One of the characteristics of a reflection hologram that could be used to define its authenticity is its precise colour in terms of its central wavelength and the width of its spectrum of reflection at its given reference angle of reconstruction. The thickness of the recording layer, exposure conditions and chemical processing details are typical means of controlling the full width at half maximum of the reflection peak, and the ability to control such parameters presents a barrier to the counterfeiter who may try to produce a label with similar characteristics.

However, if the characteristics of the hologram layer itself are difficult to reproduce, we can use the current invention to increase the level of difficulty faced by the counterfeiter by combining unique and novel colour qualities of the base or underlayer with equally recognisable and interrelated colour characteristics of the hologram.

FIG. 1 shows a holographic recording medium comprising a photosensitive layer attached to a translucent film base, which is tinted with a characteristic colour. This colour may be attributable to dyes or pigments within the carrier material, which may be PET (polyester) for example, or may be due to an underlayer. There may be one or more absorbent dyes or pigments giving rise to a single or multiple peak of absorption. The selected laser wavelength is transmitted without significant attenuation and thus the standing wave of interference in the zone where the beams overlap is recorded within the photosensitive layer.

During the processing of the layer it is possible to arrange for material to leave or enter the layer. This may be achieved in a number of ways, including solvent action in a development or bleaching solution for silver halide.

Bulking agents such as water soluble polymer can be incorporated into the silver halide layer. This principle was studied by Ilford Ltd., Mobberley. Cheshire, during the 1980's and introduced as B.I.P.S. (built in pre-swell) technology to their holographic products. Du Pont (E.I. Du Pont de Nemours. USA) have produced post-swell laminates to their range of photopolymer holographic products. Material from these films migrates into the holographic layer to increase the thickness of the finished hologram, and thus increase the wavelength of diffracted light.

Thus the wavelength of light required to reconstruct the hologram is different to the wavelength used to make the image.

Holographers often use such techniques to shift the reconstruction wavelength required by the hologram away from the wavelength of the exposure laser so as to provide a barrier to contact copying and sometimes simply to improve the aesthetic qualities of the hologram with selected colour replay.

In FIG. 2 is a schematic showing the typical layer dimensions of a holographic overlay with coloured carrier base in accordance with the present technique. The coloured layer transmits with negligible attenuation the visible, infra red or ultra violet light frequency required to reconstruct the holographic image. But it absorbs light of a nearby wavelength, thus modulating the shape of the peak representing the wavelength distribution of light reflected by the hologram, typically by limiting the width of the peak on one or both of the high and low frequency flanks of the curve.

Simultaneously, the coloured carrier foil modulates the appearance of the printed security document below it. A viewer may see a characteristic colour tint which is readily recognisable, thus aiding identification of the security document. Certain characteristics of the printed document may be accentuated or subdued by the absorption of light giving rise to certain details of the printed information by selectively increasing or decreasing the apparent contrast or brightness of the visible image.

Preferably, machine examination with monochromatic or filtered light by miniature cameras may exacerbate the contrast effects and thus the effectiveness of the ability to definitively recognise the document from the point of view of a security device.

FIG. 3a shows a spectrum of reflection of the hologram, with a relatively narrow bandwidth as controlled by chemistry and layer assembly techniques.

FIG. 3b shows a base carrier foil with two absorption peaks in close correspondence with the spectrum of the hologram and FIG. 3c shows how a characteristic modulation of the reflection spectrum of the hologram provides a readily recognisable effect. Common laser colour wavelengths, which may otherwise be used to attempt a contact copy of a security hologram, are shown on the chart to be blocked by the optical filter which is incorporated as a carrier, or base, or protective layer.

FIG. 4 shows an example of an apparatus for reading the combination holographic image with filtered spectrum and simultaneously identifying the novel protective layer by virtue of its ability to attenuate light incident and reflected from the white paper document. Alternatively and advantageously, the hologram could be attached to fully or partially overlap a printed zone in the way described in the UK Patent Application No. 0501215.8, entitled “Hologram Imaging Techniques & Holograms” and in the corresponding PCT application (ibid).

In this case, the printed detail can take advantage of the ability of the reader shown in FIG. 4 to incorporate design features which can present easily recognisable purpose-made effects for recognition by a computer controlled camera image-capture graphics system.

These effects can be categorised as truncated hologram colour spectrum characteristics, simple foil colour recognition, or complex colour analysis of the interaction of printed detail with a filtration system which manifests itself within unique or characteristic carrier layer qualities.

Light from filtered incandescent lamps of LED's is incident upon the hologram layer with the effect that a computer controlled miniature camera is able to recognise the colour qualities of the holographic diffraction grating, the film base itself due to its characteristic narrow absorption peaks, and the attenuation of the light scattered from the paper security document or the printing ink distributed upon its surface.

No doubt many other effective alternatives will occur to the skilled person and it will be understood that the invention is not limited to the described embodiments but encompasses modifications apparent to those skilled in the art lying within the spirit and scope of the claims appended hereto.

1-28. (canceled)

29. A holographic recording medium comprising:
a carrier, and
a photosensitive recording layer carried by said carrier; and
wherein said recording medium further comprises:
an optical filter, said fitter comprising a bandpass filter defining at least one optical transmission window for recording a hologram in said photosensitive recording layer.

30. A holographic recording medium as claimed in claim 29 wherein said optical filter defines two optical transmission windows at different wavelengths, one for said hologram recording, another for replay of said hologram.

31. A holographic recording medium as claimed in claim 30 wherein said photosensitive recording layer comprises a material physically processable to record said hologram using a first of said windows and to replay said recorded hologram using a second of said windows.

32. A holographic recording medium as claimed in claim 30 wherein said photosensitive recording layer comprises a material chemically processable to record said hologram using a first of said windows and to replay said recorded hologram using a second of said windows.

33. A holographic recording medium as claimed in claim 30 wherein said transmission windows are substantially non-overlapping.

34. A holographic recording medium as claimed in claim 30 wherein one of said transmission windows has a transmission of less than 50 percent at one or more laser wavelengths selected from the list 647 nm, 633 nm, 532 nm, 514 nm, 488 nm, 458 nm, 413 nm.

35. A holographic recording medium as claimed in claim 36 wherein one of said transmission windows has a transmission of less than 50 percent at all said laser wavelengths in said list.

36. A holographic recording medium as claimed in claim 29 wherein a said transmission window has a full width at half maximum of less than 100 nm, preferably less than 50 nm, and more preferably less than 20 nm or 10 nm.

37. A holographic recording medium as claimed in claim 29 wherein a said transmission window has a peak transmission of greater than 50 percent, preferably greater than 75 percent, 80 percent or 85 percent.

38. A holographic recording medium as claimed in claim 29 wherein said optical filter comprises dye within said carrier.

39. A holographic recording medium as claimed in claim 29 further comprising a filter layer to provide said optical filter.

40. A holographic recording medium, as claimed in claim 29 in which said carrier comprises polyester and in which said photosensitive recording layer comprises a material selected from gelatin, silver halide, and a photopolymer.

41. A holographic recording medium as claimed in claim 29 for volume hologram recording.

42. A holographic recording medium as claimed in claim 29 in which a said hologram has been recorded.

43. A recorded hologram incorporating an optical filter, said filter having less than 50 percent transmission at a plurality of laser wavelengths selected from 647 nm, 633 nm, 532 nm, 514 nm, 488 nm, 458 nm, 413 nm, whereby said filter is configured to inhibit replay of a hologram using any of said laser wavelengths.

44. A volume reflection hologram incorporating an optical filter, said filter having two different transmission windows, one overlapping a replay wavelength of said hologram.

45. A hologram as claimed in claim 42 mounted on a substrate said hologram including a layer recording said hologram, and wherein said recording layer is disposed between said substrate and said optical filter.

46. A hologram as claimed in claim 43 having a carrier for said recording layer, and wherein said recording layer is disposed between said substrate and said carrier.

47. A hologram as claimed in claim 46 wherein said carrier incorporates said optical filter.

48. A hologram as claimed in claim 45 wherein said substrate comprises a printed security document or banknote, and wherein said hologram is at least partially positioned over said printing.

49. A method of fabricating a hologram using a recording medium having two transmission windows, the method comprising:
recording said hologram using a first of said windows; the method further comprising:
processing said recording medium such that said recorded hologram replays within a second of said windows.

50. A method as claimed in claim 49 wherein said processing comprises processing said recording medium before said recording.

51. A method as claimed in claim 49 wherein said processing comprises processing said recording medium after said recording.

52. A method as claimed in claim 49 wherein said processing comprises physical processing.

53. A method as claimed in claim 49 wherein said processing comprises chemical processing.

54. Apparatus for reading a hologram incorporating an optical filter with at least one transmission window, the apparatus comprising:
at least one light source to illuminate said hologram at a plurality of wavelengths; and
means to determine a response of said hologram at said plurality of wavelengths.

55. Apparatus as claimed in claim 54 further comprising means to verify said hologram by verifying said hologram by verifying said response of said hologram at said plurality of wavelengths.

56. Apparatus as claimed in claim 54 wherein said plurality of wavelengths comprises a plurality of discrete wavelengths.
